(19) United States
(12) Patent Application Publication
(10) Pub. No.: US 2012/0237691 A1
(43) Pub. Date: Sep. 20, 2012

(54) METHOD OF FORMING METAL OXIDE FILM

(75) Inventors: Jonghyurk Park, Daegu (KR); Jeong Young Park, Daejeon (KR)

(73) Assignee: ELECTRONICS AND TELECOMMUNICATIONS RESEARCH INSTITUTE, Daejeon (KR)

(21) Appl. No.: 13/369,317

(22) Filed: Feb. 9, 2012

(30) Foreign Application Priority Data
Mar. 18, 2011 (KR) 10-2011-0024421

(51) Int. Cl. B05D 5/12; B05D 3/06; C23C 14/48

(52) U.S. Cl. 427/529; 427/553; 427/560; 427/123; 427/126.3

(57) ABSTRACT

Provided is a method of forming a metal oxide film. In the method, a metal oxide film is formed on a substrate using a coating solution including a metal precursor, and electrical conductivity of the metal oxide film is controlled.

### CROSS-REFERENCE TO RELATED APPLICATIONS

This U.S. non-provisional patent application claims priority under 35 U.S.C. §119 of Korean Patent Application No. 10-2011-0024421, filed on Mar. 18, 2011, the entire contents of which are hereby incorporated by reference.

### BACKGROUND OF THE INVENTION

The present invention disclosed herein relates to a method of forming a metal oxide film.

The development of industry has increased the demand for various types of electronic devices, which has brought about emergence of a transparent conductor as well as an opaque conductor. The transparent conductor is provided in the form of an optically transparent thin conductive film to be used as a transparent electrode in a display device, a photo-electronic device, or the like.

A thin film using a transparent conductor is typically formed through a vacuum deposition process. In order to form the thin film through the vacuum deposition process, expensive equipment such as a vacuum chamber is used. Thus, high costs are required to form a thin film, and there are many limitations in achieving a large area.

### SUMMARY OF THE INVENTION

The present invention provides a method of forming a metal oxide film capable of controlling electrical conductivity.

Embodiments of the present invention provide methods of forming a metal oxide film, including: forming a metal oxide film on a substrate using a coating solution including a metal precursor; and controlling electrical conductivity of the metal oxide film.

In some embodiments, the coating solution may further include nano particles, wherein the controlling of the electrical conductivity of the metal oxide film may be performed by controlling contents of the metal precursor and the nano particles in the coating solution. The nano particles may be metal particles.

In other embodiments, the controlling of the electrical conductivity of the metal oxide film may be performed by controlling a content of the metal precursor in the coating solution.

In still other embodiments, the forming of the metal oxide film may include: preparing the coating solution; providing the coating solution on the substrate to form a coating layer thereon; and drying the coating layer, wherein the controlling of the electrical conductivity of the metal oxide film may include doping the coating layer with impurities.

In even other embodiments, the doping with the impurities may include an ion implantation process.

In yet other embodiments, the impurities may include at least one of hydrogen, fluorine, nitrogen, phosphorous, arsenic, and boron.

In further embodiments, the forming of the coating layer may be performed by inkjet printing, spin coating, or screen printing.

In still further embodiments, the doping with the impurities may include controlling a temperature.

The methods may further include treating the coating layer using ultrasonic waves or electromagnetic waves.

In even further embodiments, the metal oxide film may include at least one of tin oxide, indium oxide, titanium oxide, zinc oxide, and tungsten oxide.

In yet further embodiments, the metal precursor may include at least one of metal alkoxide and metal halide.

In much further embodiments, the metal precursor may include at least one of tin, indium titanium, zinc, and tungsten.

In still much further embodiments, the coating solution may further include a reactant, and the reactant may include at least one of an acid, a base, and a surfactant.

In even much further embodiments, the metal oxide film may include multiple layers

### BRIEF DESCRIPTION OF THE DRAWINGS

The accompanying drawings are included to provide a further understanding of the present inventive concept, and are incorporated in and constitute a part of this specification. The drawings illustrate exemplary embodiments of the present inventive concept and, together with the description, serve to explain principles of the present inventive concept. In the drawings:

FIGS. 1 through 3 are flowcharts illustrating a method of forming a metal oxide film according to embodiments of the present inventive concept;

FIGS. 4 and 5 are cross-sectionals views illustrating a method of forming a metal oxide film according to an experimental example of the present inventive concept;

FIG. 6 is a graph showing optical characteristics of a metal oxide film according to an experimental example of the present inventive concept;

FIG. 7 is a graph showing electrical characteristics of a metal oxide film according to an experimental example of the present inventive concept;

FIG. 8 is a graph showing optical characteristics of a doped metal oxide film according to an experimental example of the present inventive concept;

FIG. 9 is a graph showing electrical characteristics of a doped metal oxide film according to an experimental example of the present inventive concept;

and

FIG. 10 is a cross-sectional view illustrating a method of forming a metal oxide film including a plurality of layers according to an experimental example of the present inventive concept.

### DETAILED DESCRIPTION OF PREFERRED EMBODIMENTS

Preferred embodiments of the present inventive concept will be described below in more detail with reference to the accompanying drawings. The present inventive concept may, however, be embodied in different forms and should not be constructed as limited to the embodiments set forth herein. Rather, these embodiments are provided so that this disclosure will be thorough and complete, and will fully convey the scope of the present inventive concept to those skilled in the art.

In the specification, it will be understood that when a layer (or film) is referred to as being ‘on’ another layer or substrate, it can be directly on the other layer or substrate, or intervening layers may also be present. Also, in the figures, the dimensions of layers and regions are exaggerated for clarity of illustration. Also, though terms like a first, a second, and a third are used to describe various regions and layers in various embodiments of the present inventive concept, the regions and the layers are not limited to these terms. These terms are used only to discriminate one region or layer from another region or layer. Therefore, a layer referred to as a first layer in one embodiment can be referred to as a second layer in another embodiment. An embodiment described and exemplified herein includes a complementary embodiment thereof.

Hereinafter, it will be described about an exemplary embodiment of the present inventive concept in conjunction with the accompanying drawings.

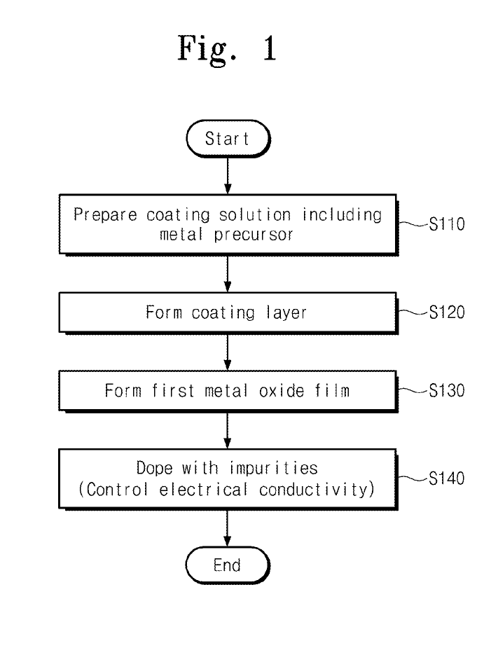

With reference to FIG. 1, a method of forming a metal oxide film according to an embodiment of the present inventive concept will now be described.

Referring to FIG. 1, a coating solution including a metal precursor is prepared in operation S110. The metal precursor may be an organic metal compound, and may be, for example, at least one of metal alkoxide and metal halide. The metal precursor may include at least one of tin (Sn), indium (In), titanium (Ti), zinc (Zn), and tungsten (W). The coating solution may include a solvent having the metal precursor diluted therein. The solvent may be hydrophilic and/or hydrophobic substances, or a mixture thereof. The coating solution may further include a reactant. The reactant may include at least one of an acid, a base, and a surfactant.

The coating solution may be provided onto a substrate to thereby form a coating layer on the substrate in operation S120. The coating layer may be formed by ink-jet printing, spin-coating, or screen printing. The substrate may be an opaque substrate such as a silicon wafer, a transparent substrate such as glass, or a flexible substrate formed of plastics.

The coating layer may be dried to thereby form a first metal oxide film in operation S130. The coating layer may be subjected to natural drying at room temperature. For example, the first metal oxide film may include at least one of tin oxide (SnO₂), indium oxide (In₂O₃), titanium oxide (TiO₂), zinc oxide (ZnO), and tungsten oxide (WO₃).

The metal oxide included in the first metal oxide film is formed by hydrolysis between the metal precursor and the coating solution or water existing in the air. In this case, the growth rate of the first metal oxide film may be controlled by controlling the concentration of the costing solution and the humidity in the air.

Additionally, the coating layer may be treated using ultrasonic waves or electromagnetic waves. This treatment can increase the growth rate of the first metal oxide film. The electromagnetic waves may be, for example, microwaves, infrared rays, visible rays, or ultraviolet rays. Also, the first metal oxide film may be subjected to a thermal treatment, which can stabilize the first metal oxide film.

The first metal oxide film may be doped with impurities to thereby control electrical conductivity of the first metal oxide film in operation S140. The impurities may include at least one of hydrogen (H), fluorine (F), nitrogen (N), phosphorus (P), arsenic (As), and boron (B). The impurity doping may be performed by ion implantation. In this case, the temperature of the substrate may be controlled.

With reference to FIG. 2, a method of forming a metal oxide film according to an embodiment of the present inventive concept will now be described.

Referring to FIG. 2, a coating solution containing a metal precursor is prepared in operation 5210. The metal precursor may be an organic metal compound. For example, the metal precursor may be at least one of metal alkoxide and metal halide. The metal precursor may include at least one of tin (Sn), indium (In), titanium (Ti), zinc (Zn), and tungsten (W). The coating solution may include a solvent having the metal precursor diluted therein. The solvent may be hydrophilic and/or hydrophobic substances, or a mixture thereof. The coating solution may further include a reactant. The reactant may include at least one of an acid, a base, and a surfactant. The content of the metal precursor in the coating solution may be controlled.

The coating solution may be provided onto a substrate to thereby form a coating layer on the substrate in operation S220. The coating layer may be formed by ink-jet printing, spin-coating, or screen printing. The substrate may be an opaque substrate such as a silicon wafer, a transparent substrate such as glass, or a flexible substrate formed of plastics.

The coating layer may be dried to thereby form a first metal oxide film in operation S230. At this case, the coating layer may be subjected to natural drying at room temperature. For example, the first metal oxide film may include at least one of tin oxide (SnO₂), indium oxide (In₂O₃), titanium oxide (TiO₂), zinc oxide (ZnO), and tungsten oxide (WO₃).

The metal oxide included in the first metal oxide film is formed by hydrolysis between the metal precursor and the coating solution or water existing in the air. In this case, the growth rate of the first metal oxide film may be controlled by controlling the concentration of the costing solution and the humidity in the air.

Additionally, the coating layer may be treated using ultrasonic waves or electromagnetic waves. The electromagnetic waves may be, for example, microwaves, infrared rays, visible rays, or ultraviolet rays. Also, the first metal oxide film may be subjected to a thermal treatment.

The electrical conductivity of the first metal oxide film can be controlled by controlling the content of the metal precursor in the coating solution.

With reference to FIG. 3, a method of forming a metal oxide film according to an embodiment of the present inventive concept will now be described.

Referring to FIG. 3, a coating solution including a metal precursor and nano particles is prepared in operation 5310. The metal precursor may be an organic metal compound. For example, the metal precursor may be at least one of metal alkoxide and metal halide. In this case, the metal precursor may include at least one of tin (Sn), indium (In), titanium (Ti), zinc (Zn), and tungsten (W). The nano particles may be metal particles. For example, the nano particles may include at least one of tin (Sn), indium (In), titanium (Ti), zinc (Zn), and tungsten (W). The coating solution may include a solvent having the metal precursor diluted therein. The solvent may be hydrophilic and/or hydrophobic substances, or a mixture thereof. The coating solution may further include a reactant. The reactant may include at least one of an acid, a base, and a surfactant. The contents of the metal precursor and the nano particles in the coating solution may be controlled.

The coating solution may be provided onto a substrate to thereby form a coating layer on the substrate in operation S320. The coating layer may be formed by ink-jet printing, spin-coating, or screen printing. The substrate may be an opaque substrate such as a silicon wafer, a transparent substrate such as glass, or a flexible substrate formed of plastics.

The coating layer may be dried to thereby form a first metal oxide film in operation S330. At this time, the coating layer may be subjected to natural drying at room temperature. For example, the first metal oxide film may include at least one of tin oxide (SnO₂), indium oxide (In₂O₃), titanium oxide (TiO₂), zinc oxide (ZnO), and tungsten oxide (WO₃).

The metal oxide included in the first metal oxide film is formed by hydrolysis between the metal precursor and the coating solution or water existing in the air. In this case, the growth rate of the first metal oxide film may be controlled by controlling the concentration of the costing solution and the humidity in the air.

Additionally, the coating layer may be treated using ultrasonic waves or electromagnetic waves. The electromagnetic waves may be, for example, microwaves, infrared rays, visible rays, or ultraviolet rays. Also, the first metal oxide film may be subjected to a thermal treatment.

The electrical conductivity of the first metal oxide film can be controlled by controlling the contents of the metal precursor and the nano particles in the coating solution.

Hereinafter, a method of forming a metal oxide film including a plurality of layers according to the present inventive concept will be described. In the following description, identical or similar contents to those in the previous embodiments will be briefly described.

According to an embodiment, a metal film may be formed on a first metal oxide film formed by performing the operations disclosed above with reference to FIGS. 1 through 3. The metal film may be formed by a vapor deposition process or a liquid-phase deposition process. The vapor deposition process may be a sputtering process, an evaporation process, or an electroplating process. The metal film is formed of metal and thus it may have higher conductivity than the first metal oxide film.

According to another embodiment, a second metal oxide film may be formed on the metal film. The second metal oxide film may be formed by performing the operations disclosed above with reference to FIGS. 1 through 3. Alternatively, the second metal oxide film may be formed by the vapor deposition process.

According to still another embodiment, a second metal oxide film may be formed on the first metal oxide film formed by performing the operations disclosed above with reference to FIGS. 1 through 3. The second metal oxide film may be formed by the vapor deposition process.

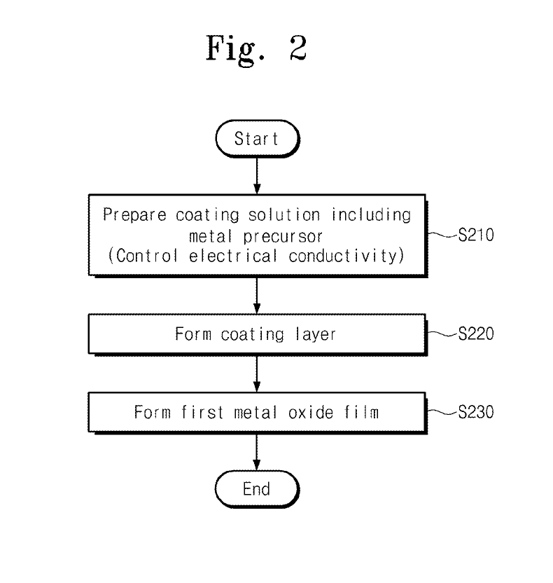

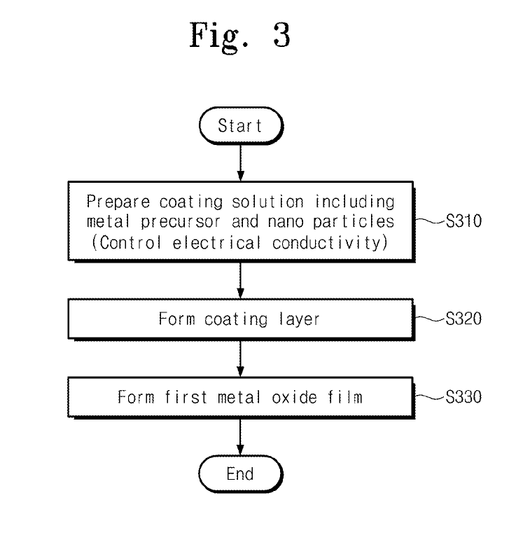

With reference to FIGS. 4 and 5, a method of forming a metal oxide film according to one experimental example of the present inventive concept and a metal oxide film provided by this method will now be described. Furthermore, referring to FIGS. 6 through 9, characteristics of the metal oxide film provided by the method disclosed above with reference to FIGS. 4 and 5 will be described.

Referring to FIG. 4, a glass substrate 400 was prepared. In this case, two parallel aluminum electrodes 420 were disposed in parallel on the glass substrate 400. The aluminum electrodes 420 may each have a thickness of approximately 100 nm.

Liquid-phase titanium isopropoxide (TIP) (Sigma-Aldrich, a purity level of 98%) was mixed with ethyl alcohol (a purity level of 98%) to thereby prepare a TIP solution of 10% by volume.

A portion of the TIP solution was subjected to spin-coating on the glass substrate 400, thus forming a coating film. The spin-coating was performed at about 2500 rpm for about 30 seconds. The coating film was dried at room temperature. In this case, the TIP was hydrolyzed with water, thereby forming a titanium oxide film (TiO₂) 430 on the glass substrate 400. The titanium oxide film 430 had a thickness of about 100 nm

The transmittance of the titanium oxide film 430 was measured. The transmittance was calculated by measuring absorbance using an IN-VIS spectrometer. In a graph disclosed in FIG. 6, the x-axis denotes a wavelength, and the y-axis denotes a transmittance. Referring to FIG. 6, the titanium oxide film 430 shows a transmittance of about 95% in a visible region.

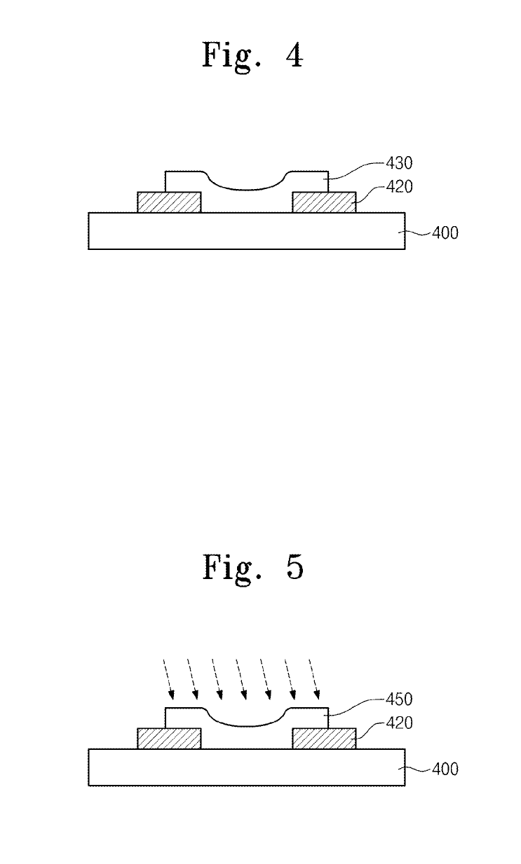

In a graph shown in FIG. 7, the x-axis is a voltage, and the y-axis is a current amount, namely a current. Referring to FIG. 7, it can be seen that current flows in a device using the titanium oxide film 430 when a voltage of about 4.3 V or higher is applied thereto. Furthermore, the current in the device using the titanium oxide film 430 shows a slow increase when the voltage increases.

Referring to FIG. 5, the titanium oxide film 430 was doped with ionized hydrogen through an ion implantation process, thereby forming a doped titanium oxide film 450. In this case, the ionized hydrogen was injected under conditions of a temperature of about 200° C. , an acceleration voltage of about 3 kV, a pressure of about 10 mTorr, and a plasma power condition of about 15 W.

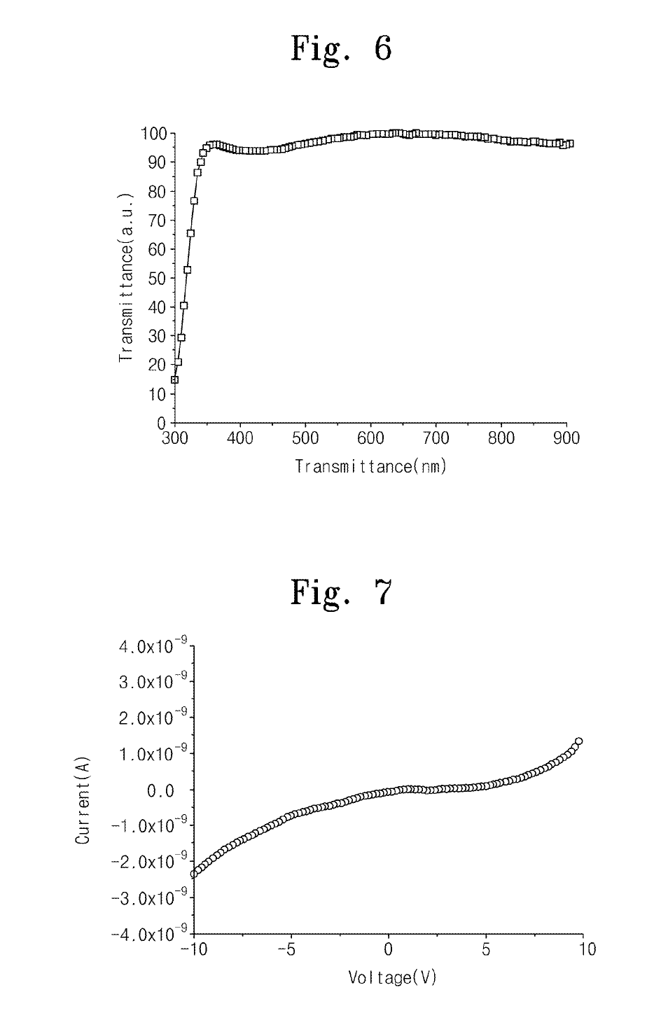

The transmittance of the doped titanium oxide film 450 was measured. In a graph shown in FIG. 8, the x-axis denotes a wavelength, and the y-axis denotes a transmittance. With reference to FIG. 8, the doped titanium oxide film 450 shows a transmittance of about 75% in a visible region.

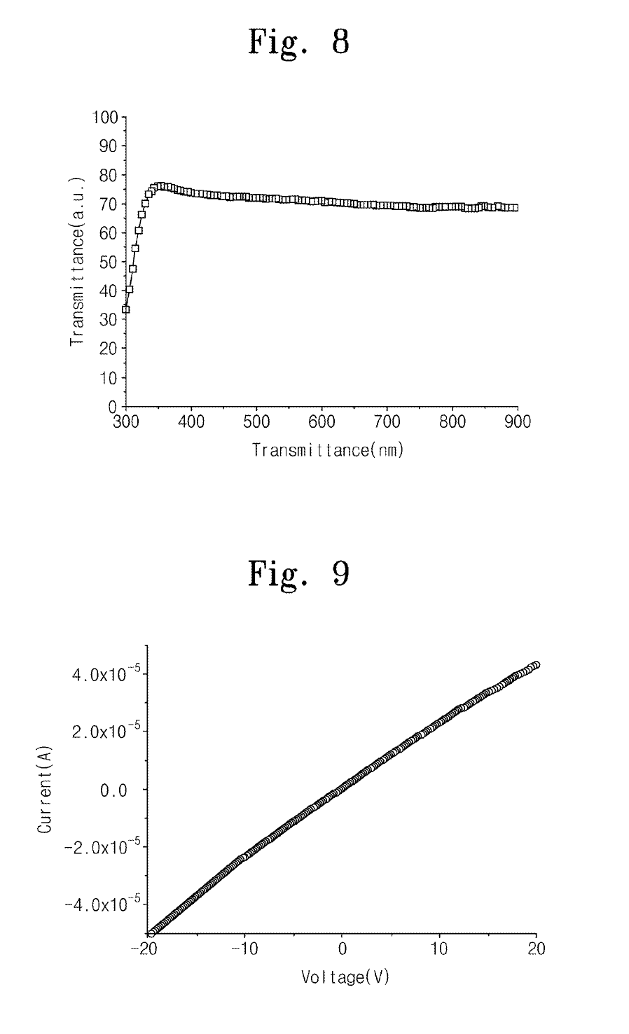

In a graph illustrated in FIG. 9, the x-axis denotes a voltage, and the y-axis denotes a current amount. Referring to FIG. 9, the current in a device using the doped titanium oxide film linearly shows a linear increase as a voltage exceeding about 0V is applied thereto.

Referring to FIGS. 6 through 9, the transmittance and conductivity of the metal oxide film may be controlled according to a formation temperature, whether or not doping is performed, and a doping temperature. Thus, according to embodiments of the present inventive concept, a metal oxide film having desired properties can be formed by controlling the formation temperature and doping conditions of the metal oxide film.

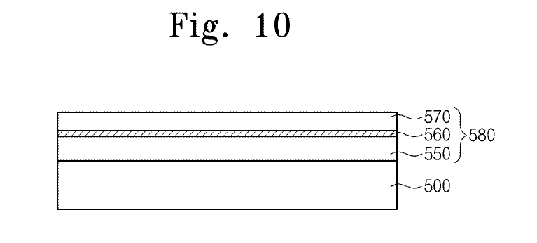

Referring to FIG. 10, a method of forming a metal oxide film including a plurality of layers according to an experimental example of the present inventive concept, and a metal oxide film provided by this method will now be described.

Referring to FIG. 10, a first doped titanium oxide film 550 is formed on a glass substrate 500 through the same process described above with reference to

FIGS. 4 and 5. The first doped titanium oxide film 550 has a resistance value of about 10 kΩ/sq (about 0.1 Ω/cm in specific resistance).

Silver (Ag) is subjected to vacuum deposition, thereby forming a metal film 560 of about 10 nm on the first doped titanium oxide film 550.

A second doped titanium oxide film 570 is formed on the metal film 560 through the same process as the first doped titanium oxide film 550.

A metal oxide film 580 including the first doped titanium oxide film 550, the metal film 560, and the second doped titanium oxide film 570 has a resistance value of a few kΩ/sq. Thus, the multi-layered metal oxide film is formed to include thin metal films therein, allowing the metal oxide film to be controlled in electrical conductivity.

As set forth above, according to embodiments of the present inventive concept, the electrical conductivity of a metal oxide film can be controlled by adjusting the concentration of a metal precursor solution prepared to form the metal oxide film and/or the doping conductions of an ion implantation process for forming the metal oxide film. Thus, the metal oxide film may have insulating properties, semiconductor properties, and conductive properties as desired. Controlling the electrical conductivity of the metal oxide film according to embodiments of the present inventive concept enables the metal oxide film to be applicable to a variety of devices.

According to one embodiment of the present inventive concept, since a metal oxide film can be formed through a process using a solution at room temperature, the uniform formation thereof can be attained with lower costs at a lower temperature than in a case where a metal oxide film is formed through a deposition process using a chamber, such as sputtering. Furthermore, processes according to embodiments of the present inventive concept are easily applicable to large-sized substrates and have less limitation as to substrates.

The above-disclosed subject matter is to be considered illustrative, and not restrictive, and the appended claims are intended to cover all such modifications, enhancements, and other embodiments, which fall within the true spirit and scope of the present inventive concept. Thus, to the maximum extent allowed by law, the scope of the present inventive concept is to be determined by the broadest permissible interpretation of the following claims and their equivalents, and shall not be restricted or limited by the foregoing detailed description.

What is claimed is:

1. A method of forming a metal oxide film, comprising:
forming a metal oxide film on a substrate using a coating solution including a metal precursor; and
controlling electrical conductivity of the metal oxide film.

2. The method of claim 1, wherein the coating solution further comprises nano particles,
wherein the controlling of the electrical conductivity of the metal oxide film is performed by controlling contents of the metal precursor and the nano particles in the coating solution.

3. The method of claim 2, wherein the nano particles are metal particles.

4. The method of claim 1, wherein the controlling of the electrical conductivity of the metal oxide film is performed by controlling a content of the metal precursor in the coating solution.

5. The method of claim 1, wherein the forming of the metal oxide film comprises:
preparing the coating solution;
providing the coating solution on the substrate to form a coating layer on the substrate; and
drying the coating layer,
wherein the controlling of the electrical conductivity of the metal oxide film comprises doping the coating layer with impurities.

6. The method of claim 5, wherein the doping with the impurities comprises an ion implantation process.

7. The method of claim 5, wherein the impurities comprise at least one of hydrogen, fluorine, nitrogen, phosphorous, arsenic, and boron.

8. The method of claim 5, wherein the forming of the coating layer is performed by inkjet printing, spin coating, or screen printing.

9. The method of claim 5, wherein the doping with the impurities comprises controlling a temperature.

10. The method of claim 5, further comprising treating the coating layer using ultrasonic waves or electromagnetic waves.

11. The method of claim 1, wherein the metal oxide film comprises at least one of tin oxide, indium oxide, titanium oxide, zinc oxide, and tungsten oxide.

12. The method of claim 1, wherein the metal precursor comprises at least one of metal alkoxide and metal halide.

13. The method of claim 1, wherein the metal precursor comprises at least one of tin, indium titanium, zinc, and tungsten.

14. The method of claim 1, wherein the coating solution further comprises a reactant, the reactant including at least one of an acid, a base, and a surfactant.

15. The method of claim 1, wherein the metal oxide film comprises multiple layers.
